(19) United States
(12) Patent Application Publication
(10) Pub. No.: US 2002/0127867 A1
(43) Pub. Date: Sep. 12, 2002

(54) Semiconductor devices having a hydrogen diffusion barrier layer and methods of fabricating the same

(75) Inventor: Yong-Tak Lee, Kyunggi-do (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 10/093,557

(22) Filed: Mar. 7, 2002

(30) Foreign Application Priority Data
Mar. 12, 2001 (KR) 2001-12601

(51) Int. Cl. H01L 21/20; H01L 21/311

(52) U.S. Cl. 438/694; 438/785; 438/906; 438/396

(57) ABSTRACT

A semiconductor device having a hydrogen diffusion barrier layer and a fabrication method thereof are provided. An ozone flushing treatment is performed before and/or after forming the hydrogen diffusion barrier layer. The hydrogen diffusion barrier layer can be formed of aluminum oxide or tantalum oxide. The ozone flushing treatment is preferably performed with an ozone concentration of about 100 to 300 g/m3 at a temperature of about 200 to 550° C. for approximately 1 to 10 minutes.

This application relies for priority upon Korean Patent Application No. 2001-12601, filed on Mar. 12, 2001, the contents of which are herein incorporated by reference in their entirety.

### FIELD OF THE INVENTION

The present invention relates to semiconductor devices and methods of fabricating the same, and more particularly to semiconductor devices having a hydrogen diffusion barrier layer and methods of fabricating the same.

### BACKGROUND OF THE INVENTION

As semiconductor devices become more highly integrated, an area occupied by discrete devices, such as capacitors, has been reduced. Memory devices such as DRAMs employ capacitors as data storage media of memory cells. A cell capacitor should have large capacitance to enhance cell characteristics, such as a refresh characteristic. Various methods have been proposed in order to increase the capacitance.

The cell capacitor comprises two electrodes that face each other with a dielectric layer disposed therebetween. The capacitance of the cell capacitor is proportional to a dielectric constant of the dielectric layer and to an overlapping area of the electrodes. Capacitance is inversely proportional, on the other hand, to a thickness of the dielectric layer. To increase capacitance, therefore, it is necessary to employ a thin dielectric layer, a dielectric layer having a high dielectric constant, or electrodes having a large surface area.

Each of these methods has its own problems, however. When the dielectric layer is formed too thin, for example, the capacitor suffers from leakage current. When the surface areas of the electrodes are increased in a limited area, a height of the capacitor is increased. This generates a large step difference between a cell array region and a peripheral circuit region and causes difficulty in subsequent processes.

For these reasons, a dielectric layer having a high dielectric constant has been widely used. Ferroelectric materials such as barium strontium titanate (BST), lead zirconium titanate (PZT), or strontium barium tantalum (SBT) are attractive candidates for use in forming the high dielectric constant dielectric layer. In particular, these ferroelectric materials can be used as a dielectric layer of a ferroelectric random access memory (FRAM).

Due to remnant polarization (Pr), a ferroelectric material has two stable states that are changed by an externally applied electric field. The remnant polarization is maintained even after the external electric field is eliminated. The Pr characteristic is beneficial for digital memory devices, especially binary memory devices, which have become widely used.

There are still many problems encountered in fabricating FRAM devices. The ferroelectric material, for example, readily reacts with a polysilicon layer, which is widely used as the electrode. To avoid this, the electrode can be a layer formed of a noble metal such as platinum (Pt) or a conductive metal oxide such as ruthenium oxide (RuO₂). When the electrode is formed of a noble metal or a conductive metal oxide, however, it is difficult to pattern the resulting layer using an etching technique to form the electrode. In addition, the polarization characteristic of the ferroelectric layer is degraded during the fabrication processes. More specifically, remnant polarization is decreased during the formation of an interlayer dielectric layer, an inter-metal dielectric layer, and a passivation layer, or the like.

For example, a silicon oxide layer used as the interlayer dielectric layer is usually formed by chemical vapor deposition (CVD) using silane (SiH₄) as a silicon source gas and N₂O or O₂ as an oxygen source gas. While the CVD oxide layer is formed, hydrogen gas is inevitably generated. The CVD oxide layer therefore contains many hydrogen atoms. These hydrogen atoms are easily diffused into the ferroelecric layer during a subsequent thermal process. The hydrogen atoms become bonded with oxygen atoms in the ferroelectric layer, thereby chemically reducing the ferroelectric layer. The ferroelectric layer thereby loses its own crystalline (perovskite) structure. The polarization characteristic of the ferroelectric layer is thereby significantly degraded.

To prevent the deterioration of the ferroelectric layer by hydrogen, a hydrogen diffusion barrier layer is formed to cover the ferroelectric capacitor prior to the formation of the interlayer dielectric layer. Hydrogen is also generated, however, during the formation of the hydrogen diffusion barrier layer, thereby degrading the ferroelectric layer.

Furthermore, a passivation layer is formed after a metallization process. Since the passivation layer is formed of a silicon oxide layer, a silicon nitride layer, a silicon oxynitride layer, or a combination thereof, silane gas is used as a silicon source gas in a deposition process. The passivation process therefore also generates hydrogen gas, deteriorating the ferroelectric layer as described above.

### SUMMARY OF THE INVENTION

It is an object of the present invention to provide methods of forming a reliable hydrogen diffusion barrier layer that are capable of preventing the ferroelectric layer from being damaged due to hydrogen.

It is another object of the invention to provide methods of fabricating a ferroelectric random access memory device without degradation of the ferroelectric capacitor, and to provide ferroelectric random access memory devices fabricated thereby.

To help achieve the foregoing objects, an aspect of the present invention includes performing an ozone flushing treatment. The ozone flushing treatment can be carried out either before or after forming the hydrogen diffusion barrier layer. Alternatively, the ozone flushing treatment may be performed both before and after forming the hydrogen diffusion barrier layer. Using the ozone flushing treatment, it is possible to minimize hydrogen damage to the ferroelectric layer during the formation of the hydrogen diffusion barrier layer. It is also possible to form a reliable hydrogen diffusion barrier layer, since the ozone flushing technique treats the surface of the underlying layer. The ozone flushing treatment is preferably performed at a temperature of between about 200 to 550° C. for approximately 1 to 10 minutes. The ozone concentration is preferably between about 100 to 300 grams/m³.

An aluminum oxide layer (Al₂O₃) or a tantalum oxide layer (Ta₂O₅) can be used as the hydrogen diffusion barrier layer. The aluminum oxide layer can be formed using trimethyl aluminum (Al(CH₃)₃) as an aluminum source material and using H₂O or ozone as an oxygen source material. The Ta₂O₅ layer can be formed using Ta(OC₂H₅)₅ and O₂ as a tantalum and an oxygen source gas, respectively.

When the aluminum oxide layer is formed using an atomic layer deposition (ALD) technique, ozone flushing treatment is performed first and an aluminum precursor such as trimethyl aluminum is supplied and chemically adsorbed (chemisorbed) on the underlying layer. Thereafter, physically adsorbed (physisorbed) or non-chemisorbed aluminum precursors are removed using an inert gas as a purging gas. Oxygen precursors are then supplied and chemically deposited to form a single atomic layer of aluminum oxide through a chemical reaction or chemical exchange. Unreacted aluminum oxide is then removed using an inert gas, thereby leaving the single atomic layer of aluminum oxide on the underlying layer. The above procedures are repeatedly performed to form an aluminum oxide layer having a desired thickness. An ozone flushing treatment may then be performed again.

A CVD technique can also be used. Unlike the ALD technique, however, when the aluminum oxide layer is formed using a CVD technique, aluminum and oxygen precursors are concurrently rather than sequentially supplied. The aluminum oxide layer formed using the ALD technique typically exhibits better step coverage and more uniform film quality. In either technique, however, is more preferable to use ozone rather than H₂O as the oxygen precursor to effectively prevent hydrogen damage.

A method of forming a hydrogen diffusion barrier layer according to a preferred embodiment of the present invention is applicable to the fabrication of a ferroelectric random access memory (FRAM) device employing ferroelectric capacitors. In this method, a lower hydrogen diffusion barrier layer is formed on the substrate where the ferroelectric capacitors are formed, and an interlayer insulating layer is then formed on the lower hydrogen diffusion barrier layer. An upper hydrogen diffusion barrier layer can be formed before the formation of a passivation layer. Each of the hydrogen diffusion barrier layers prevents hydrogen atoms from being diffused into the ferroelectric capacitors during the formation of the interlayer insulating layer and the passivation layer. This method can thereby prevent the deterioration of a ferroelectric layer of the respective ferroelectric capacitors.

In addition, an ozone flushing treatment is preferably performed before and/or after forming the respective hydrogen diffusion barrier layers in order to obtain better film quality of the hydrogen diffusion barrier layers and prevent the deterioration of the ferroelectric layer while forming the hydrogen diffusion barrier layers. The ozone flushing treatment provides oxygen atoms to minimize the oxygen vacancies in the ferroelectric layer. As a result, deterioration of feroelectric layer due to hydrogen atoms is minimized.

In one embodiment of the present invention, a method of forming a ferroelectric random access memory includes performing a metallization process for forming metal interconnections before a passivation process. An insulation layer is preferably formed before forming the upper hydrogen diffusion barrier layer in order to protect the metal interconnections.

According to yet another aspect of the invention, a FRAM device has ferroelectric capacitors formed over a semiconductor substrate. Each of the ferroelectric capacitors includes a lower electrode, a ferroelectric layer, and an upper electrode, which have been sequentially formed on the semiconductor substrate. A lower interlayer insulating layer may be interposed between the ferroelectric capacitors and the semiconductor substrate. The substrate having the ferroelectric capacitors is covered with a lower hydrogen diffusion barrier layer. The lower hydrogen diffusion barrier layer is covered with an upper interlayer insulating layer. Metal interconnections are disposed on the upper interlayer insulating layer. At least one of the metal interconnections is electrically connected to the upper electrode through a contact hole that penetrates the upper interlayer insulating layer and the lower hydrogen diffusion barrier layer. The substrate having the metal interconnections is covered with an upper hydrogen diffusion barrier layer. The upper hydrogen diffusion barrier layer is covered with a passivation layer.

In an alternate embodiment of the invention, the upper and lower hydrogen diffusion barrier layers are formed of aluminum oxide (Al₂O₃) or tantalum oxide (Ta₂O₅) and have a thickness of approximately 100 to 1,000 angstroms.

An insulation layer is preferably interposed between the upper interlayer dielectric layer and the upper hydrogen diffusion barrier layer. The insulation layer covers the metal interconnections as well as the upper interlayer insulating layer. The insulation layer preferably comprises a PE-TEOS (plasma-enhanced tetra-ethyl-ortho-silicate) layer having a thickness of approximately 1,000 to 6,000 angstroms.

### BRIEF DESCRIPTION OF THE DRAWINGS

The foregoing and other objects and advantages of the present invention will become readily apparent from the following detailed description of preferred embodiments, made with reference to the accompanying drawings, in which:

FIG. 1 is a cross-sectional view of a ferroelectric random access memory device having a hydrogen diffusion barrier layer formed according to a preferred embodiment of the present invention; and

FIGS. 2A through 2G are cross-sectional views illustrating a method of forming a ferroelectric random access memory device according to a preferred embodiment of the present invention.

### DETAILED DESCRIPTION OF PREFERRED EMBODIMENTS

Preferred embodiments of the present invention will now be described more fully hereinafter with reference to the accompanying drawings. It should be noted, however, that this invention may be embodied in many different forms and should not be construed as being limited to the preferred embodiments set forth herein. Rather, these embodiments are provided to convey the principles of the invention to those skilled in the art. It should also be noted that the thickness of layers and regions are exaggerated in the drawings for clarity.

With respect to certain specific terms used in the following description, it should be understood that the term “on” is used in a broad descriptive sense. When a layer is referred to as being “on” another layer or substrate, that layer can be arranged either directly above the other layer or substrate or can have intervening layers therebetween.

According to a preferred embodiment of this invention, a method for forming a hydrogen diffusion barrier layer prevents the deterioration of a semiconductor device due to hydrogen gas generated during the formation of an insulation layer in a semiconductor fabrication process. A method for minimizing damage caused by the hydrogen diffusion barrier layer itself is also provided.

According to this embodiment of the present invention, a hydrogen diffusion barrier layer is formed before forming an insulation layer. An ozone (O₃) flushing treatment is preferably performed both before and after forming the hydrogen diffusion barrier layer, but could be performed either before or after. The ozone flushing treatment supplies oxygen radicals to the underlying layer to minimize the chemical reduction of that layer due to hydrogen atoms generated during subsequent processes. When performed before the formation of the hydrogen diffusion barrier layer, therefore, the ozone flushing treatment prepares the surface of the underlying layer for the barrier layer by creating ideal surface conditions. The film quality of the hydrogen diffusion barrier layer is thereby improved. Ozone flushing treatment performed after forming the hydrogen diffusion barrier layer stabilizes the hydrogen diffusion barrier layer.

The ozone flushing treatment is preferably performed at a temperature of between about 200 to 550° C. for approximately 1 to 10 minutes. The ozone concentration is preferably about 100 to 300 g/m³. The hydrogen diffusion barrier layer can be formed using an atomic layer deposition (ALD) technique or a chemical vapor deposition (CVD) technique. The hydrogen diffusion barrier layer is preferably an aluminum oxide layer (Al₂O₃) or a tantalum oxide layer (Ta₂O₅). The hydrogen diffusion barrier layer is most preferably formed using the ALD technique, since the ALD technique exhibits better step coverage and more uniform film quality as compared to the CVD technique. According to the ALD technique, a single atomic layer is repeatedly stacked to form a layer having a desired thickness. In the ALD technique, at least two kinds of source gases are alternately supplied. In the CVD technique, on the other hand, the two kinds of source gases are concurrently supplied.

A method of forming the aluminum oxide (Al₂O₃) layer using the ALD technique will now be described. In this method, trimethyl aluminum (TMA; Al(CH₃)₃) is used as an aluminum precursor and ozone is used as an oxygen precursor. H₂O could also be used as the oxygen precursor.

An ozone flushing treatment is first applied to a surface of the semiconductor substrate where a hydrogen diffusion barrier layer is to be formed. Next, aluminum precursors such as trimethyl aluminum are supplied to the substrate. The aluminum precursors are chemically adsorbed (chemisorbed) on the surface of the semiconductor substrate. The unreacted aluminum precursors are subsequently purged, using an inert gas such as nitrogen, argon, or helium.

Oxygen precursors are then supplied. The oxygen precursors react with the aluminum precursors adsorbed on the semiconductor substrate. As a result, a single atomic layer of aluminum oxide is formed. A purging gas is then supplied to remove unreacted oxygen precursors that exist on the semiconductor substrate. The foregoing steps are repeatedly performed to form an aluminum oxide (Al₂O₃) layer having a desired thickness. A tantalum oxide layer could also be formed to a desired thickness using the above-described method. In that case, however, tantalum precursors are used in place of aluminum precursors.

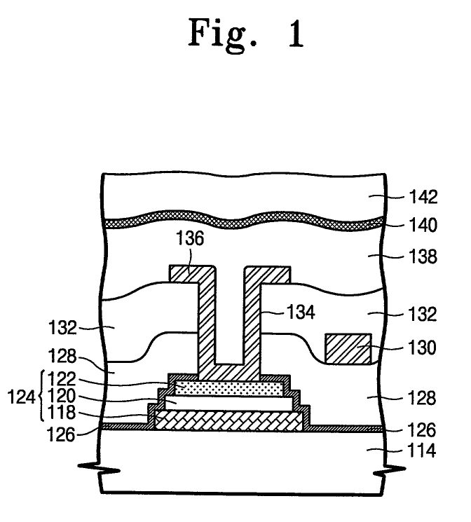

FIG. 1 is a cross-sectional view of a ferroelectric random access memory including a hydrogen diffusion barrier layer, formed in accordance with an embodiment of the present invention. Referring to FIG. 1, a ferroelectric capacitor 124 is disposed on a semiconductor substrate (not shown). The ferroelectric capacitor 124 comprises a sequentially stacked lower electrode 118, ferroelectric layer 120, and upper electrode 122. The semiconductor substrate may also include a transistor (not shown), formed at a predetermined region thereof.

A lower interlayer dielectric layer 114 can be interposed between the transistor and the ferroelectric capacitor 124. The substrate having the ferroelectric capacitor 124 is covered with a lower hydrogen diffusion barrier layer 126. An upper interlayer dielectric layer 128 and an inter-metal dielectric layer 132 are sequentially stacked on the lower hydrogen diffusion barrier layer 126. The lower hydrogen diffusion barrier layer 126 is formed to prevent the ferroelectric layer 120 from being degraded due to hydrogen atoms generated during the formation of the upper interlayer dielectric layer 128 and the inter-metal dielectric layer 132.

A metal interconnection 136 is disposed on the inter-metal dielectric layer 132. The metal interconnection 136 is electrically connected to the upper electrode 122 through a via hole 134 that penetrates the inter-metal dielectric layer 132, the upper interlayer dielectric layer 128, and the lower hydrogen diffusion barrier layer 126. The substrate having the metal interconnection 136 is covered with an upper hydrogen diffusion barrier layer 140. In addition, a passivation layer 142 is disposed on the upper hydrogen diffusion barrier layer 140.

The upper hydrogen diffusion barrier layer 140 is formed to prevent hydrogen atoms, generated during the formation of the passivation layer 142, from being diffused into the ferroelectric capacitor 124. A buffer insulation layer 138 can be interposed between the metal interconnection 136 and the upper hydrogen diffusion barrier layer 140. The buffer insulation layer 138 protects the metal interconnection 136. The inter-metal dielectric layer 132 need not be formed. Another metal interconnection 130 can be interposed between the upper interlayer dielectric layer 128 and the inter-metal dielectric layer 132.

The lower hydrogen diffusion barrier layer 126 and the upper hydrogen diffusion barrier layer 140 prevent the characteristic deterioration of the ferroelectric layer 120 of the ferroelectric capacitor 124 caused by hydrogen atoms generated during the formation of the interlayer dielectric layer 128 and the passivation layer 142.

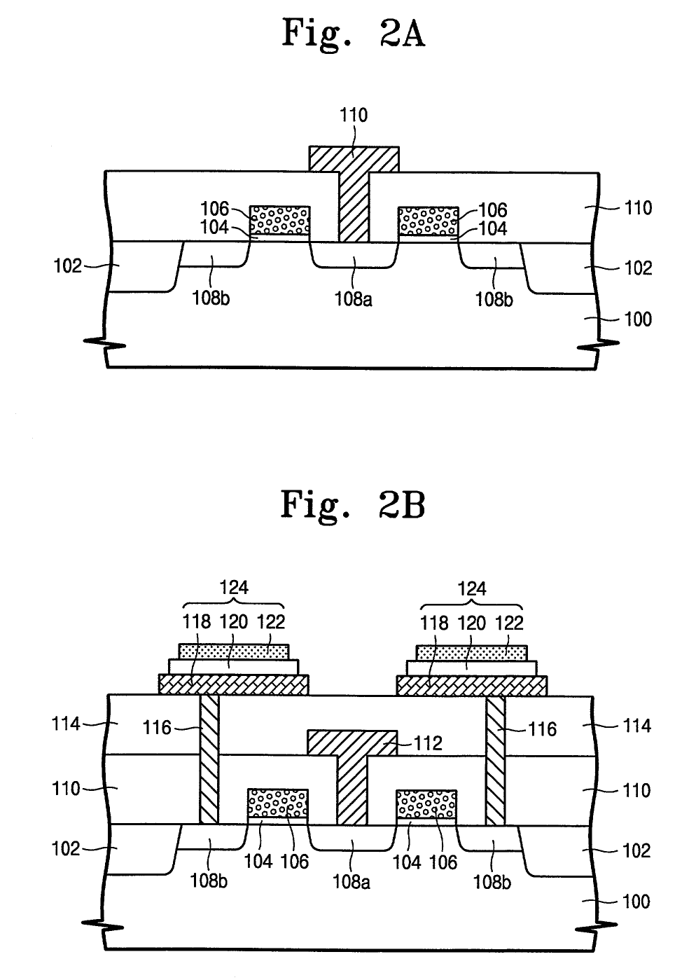

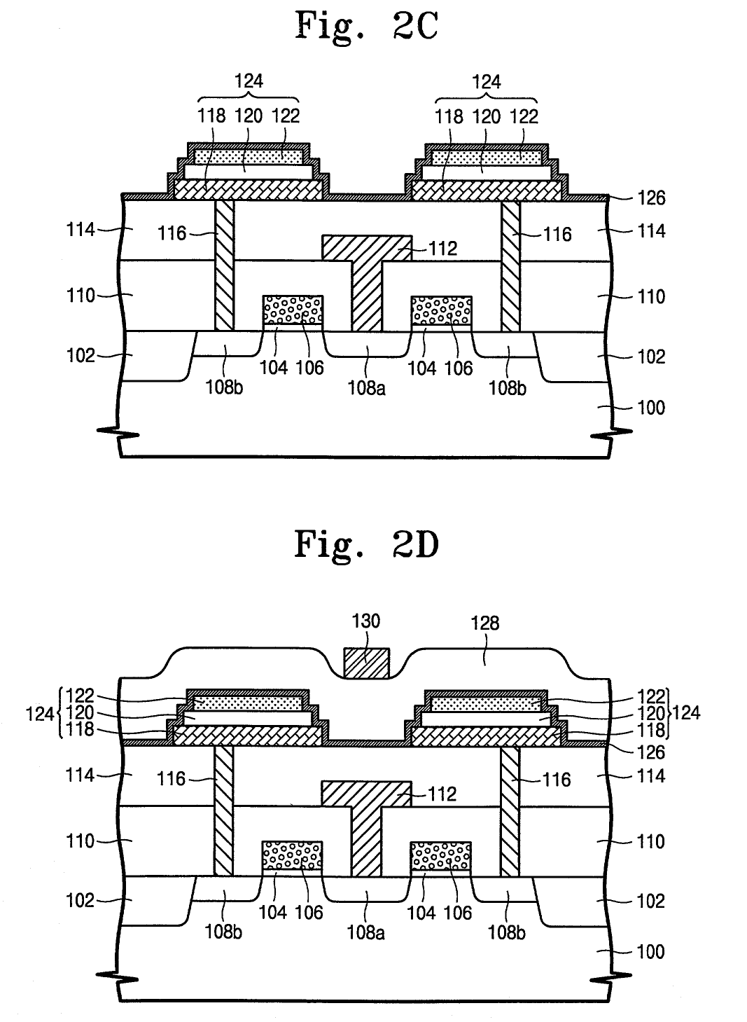

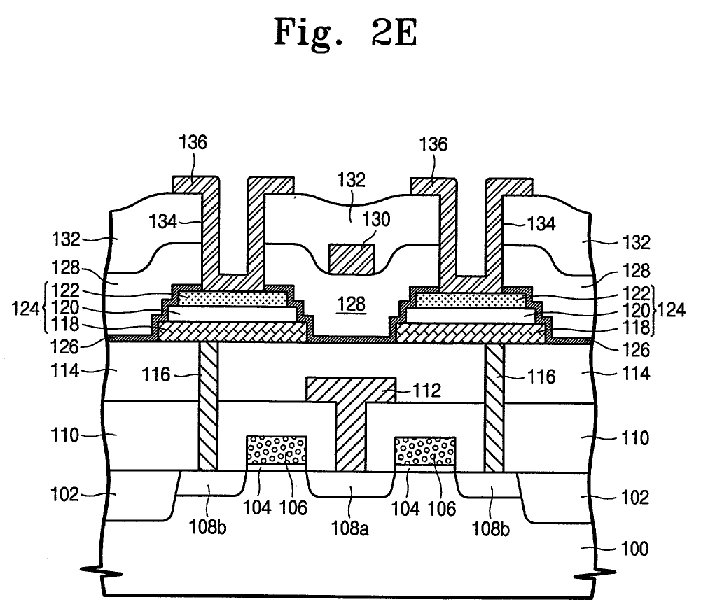

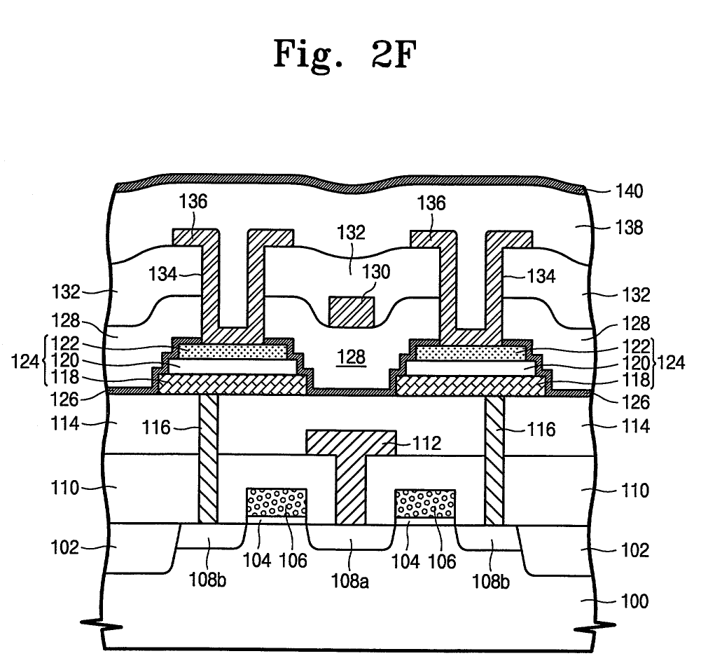

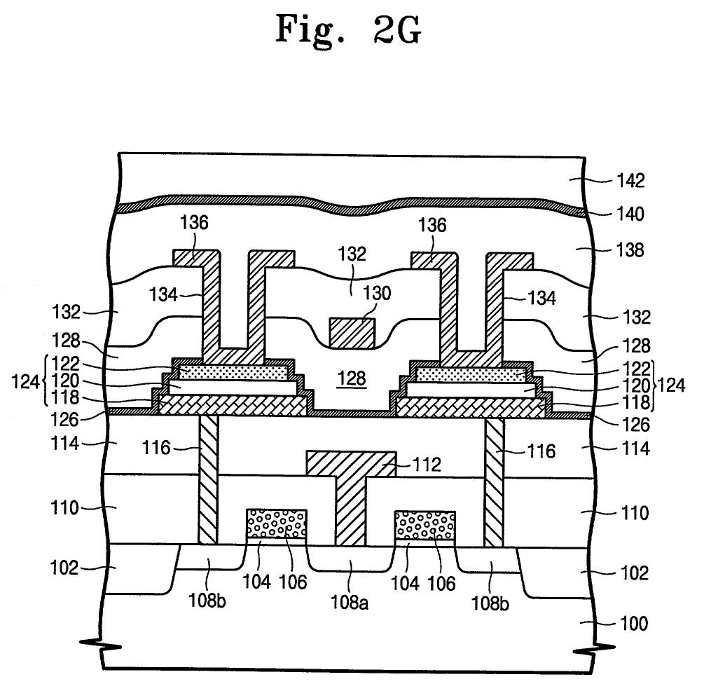

In accordance with another preferred embodiment of the present invention, a method of forming an FRAM that includes a hydrogen diffusion barrier layer will now be described with reference to FIGS. 2A to 2G. Referring first to FIG. 2A, a device isolation region 102 is formed at a predetermined region of a semiconductor substrate 100, thereby defining an active region. Transistors are then formed at the active region using a conventional complementary metal oxide semiconductor field effect transistor (CMOS-FET) process. Each of the transistors comprises source and drain regions 108b and 108a, respectively, formed at the active region and spaced apart from each other, and a gate electrode 106 formed over a channel region between the source region 108b and the drain region 108a. The gate electrode 106 is insulated from the channel region by a gate oxide layer 104 interposed between the gate electrode 106 and the channel region. The gate electrode 106 can be formed of polysilicon or tungsten polycide.

A first interlayer dielectric layer 110 is subsequently formed on the surface of the substrate 100 including the transistors. The first interlayer dielectric layer 110 is preferably planarized using an etch-back process or a chemical mechanical polishing (CMP) process. The first interlayer dielectric layer 110 may comprise a borophosphosilicate glass (BPSG) layer, a phosphorous silicate glass (PSG) layer, an undoped silicate glass (USG) layer, or a tetra-ethyl-ortho-silicate (TEOS) layer. The first interlayer dielectric layer 110 is patterned to form a bit line contact hole exposing the drain region 108a of the transistor. A conductive layer is then formed on the substrate having the bit line contact hole. The conductive layer is patterned to form a bit line 112 covering the bit line contact hole. The conductive layer can be formed of tungsten. Alternatively, a bit line contact plug (not shown) that fills the bit line contact hole may be formed before forming the conductive layer. As a result, the bit line 112 is electrically connected to the drain region 108a.

Referring to FIG. 2B, a second interlayer dielectric layer 114 is formed on the surface of the substrate having the bit line 112. The second interlayer dielectric layer 114 may be formed of BPSG. The second interlayer dielectric layer 114 and the first interlayer dielectric layer 110 are patterned to form a capacitor contact hole exposing the source regions 108b. A conductive material layer for a plug is subsequently formed on the second interlayer dielectric layer 114 and within the capacitor contact hole. The conductive material layer is then planarized until the second interlayer dielectric layer 114 is exposed, thereby forming a capacitor contact plug 116 in the capacitor contact hole.

The formation of the capacitor contact plug 116 and the planarization of the second interlayer dielectric layer 114 are performed concurrently. The planarization of the second interlayer dielectric layer 114 helps improve the step coverage of a ferroelectric layer to be formed in a subsequent process. The capacitor contact plug 116 can be formed of doped polysilicon, tungsten (W), tantalum (Ta), ruthenium (Ru), iridium (fr), platinum (Pt), tungsten silicide (WSi₂), tungsten nitride (WN), osmium (Os), or a combination thereof.

After forming the capacitor contact plug 116, a lower electrode layer, a ferroelecric layer, and an upper electrode layer are sequentially formed thereon. The lower electrode layer may be formed of a noble metal such as platinum (Pt), a conductive oxide such as iridium oxide (IrO₂), or a combination thereof. The noble metal could also be iridium (Ir), ruthenium (Ru), rhodium (Rh), Osmium (Os), or palladium (Pd) instead of platinum (Pt). The conductive oxide layer could be formed of RuO₂, (Ca,Sr)RuO₃, or LaSrCoO₃ instead of iridium oxide. The ferroelectric layer could be formed of BaTiO₃, SrTiO₃, (Ba,Sr)TiO₃, Bi4Ti₃O₁₂, PbTiO₃, Pb(Zr,Ti)O₃, (Pb,La)(Zr,Ti)O₃, or (Sr,Ba)TiO₃. Further, the upper electrode layer could also be formed of iridium, ruthenium, platinum, iridium oxide, or a combination therof.

The upper electrode layer, the ferroelectric layer and the lower electrode layer are patterned to form ferroelectric capacitors 124 on the respective capacitor contact plugs 116. As a result, each of the ferroelectric capacitors 124 comprises a lower electrode 118, a ferroelectric layer 120, and an upper electrode 122.

Referring to FIG. 2C, after forming the ferroelectric capacitors 124, a lower hydrogen diffusion barrier layer 126 is formed on the second interlayer dielectric layer 114 and the ferroelectric capacitors 124. The lower hydrogen diffusion barrier layer 126 is preferably formed of aluminum oxide (Al₂O₃) or tantalum oxide (Ta₂O₅). For the aluminum oxide layer, it is more preferable to use an ALD technique rather than a CVD technique. This is because a lower hydrogen diffusion barrier layer 126 formed according to the ALD technique exhibits better film quality than one formed in accordance with the CVD technique.

An ozone flushing treatment is performed before and/or after forming the lower hydrogen diffusion barrier layer 126. The ozone flushing treatment is performed at a temperature of between about 200 to 500° C. for approximately 1 to 10 minutes. The ozone concentration is preferably about 100 to 300 g/m³. The lower hydrogen diffusion barrier 126 is preferably formed to a thickness of approximately 100 to 1000 angstroms.

Referring to FIG. 2D, a third interlayer dielectric layer 128 is formed on the lower hydrogen diffusion barrier layer 126. The third interlayer dielectric layer 128 may comprise a USG layer, a PSG layer, a PE-TEOS layer, or a SiH₄ based plasma oxide layer. A stripe line 130 is subsequently formed on the third interlayer dielectric layer 128. The stripe line 130 controls two or four gate electrodes 106 (i.e., two or four word lines) through a decoder. The stripe line 130 provides a main word line. The stripe line 130 is formed of metal layer such as an aluminum layer. Though not shown in the figure, the stripe line 130 is electrically connected to the gate electrodes 106 through contact holes that penetrate a predetermined region of the third interlayer dielectric layer 128, the lower hydrogen diffusion barrier layer 126, the second interlayer dielectric layer 114, and the first interlayer dielectric layer 110. The process of forming the stripe line 130 may be omitted, however.

Referring to FIG. 2E, an inter-metal dielectric layer 132 is formed on the substrate having the stripe line 130. The inter-metal dielectric layer 132 may be made of USG, PSG, PE-TEOS, or SiH₄ based plasma oxide. Hydrogen may be generated during a deposition process of the third interlayer dielectric layer 128 and/or the inter-metal dielectric layer 132. However, because the lower hydrogen diffusion barrier layer 126 covers the ferroelectric capacitors 124, deterioration of the ferroelectric layer 120 due to the hydrogen is prevented.

Next, the inter-metal dielectric layer 132, the third interlayer dielectric layer 128, and the lower hydrogen diffusion barrier layer 126 are patterned to form a via hole 134 exposing the upper electrodes 122 of the ferroelectric capacitors 124. A conductive material layer is then formed in the via hole 134 and on the inter-metal dielectric layer 132. The conductive material layer is patterned to form plate lines 136. Each of the plate lines 136 is electrically connected to a respective upper electrode 122. The plate lines 136 are preferably formed of aluminum having a low conductivity.

Referring to FIG. 2F, an upper hydrogen diffusion barrier layer 140 is formed over the plate lines 136. Before forming the upper hydrogen diffusion barrier layer 140, a buffer insulation layer 138 may be formed over the plate lines 136. The buffer insulation layer 138 is preferably made of PE-TEOS, which is capable of being deposited at a low temperature (i.e., about 200° C.). The buffer insulation layer 138 is preferably formed to a thickness of about 1000 to 6000 angstroms.

The upper hydrogen diffusion barrier layer 140 is formed in the same manner as the lower hydrogen diffusion barrier layer 126. In addition, an ozone flushing treatment may be performed before and/or after forming the upper hydrogen diffusion barrier layer 140. This ozone flushing treatment is preferably carried out at a temperature of about 200 to 550° C. for approximately 1 to 10 minutes. The ozone concentration is preferably about 100 to 300 g/m³. The upper hydrogen diffusion barrier layer 140 is preferably formed to a thickness of about 100 to 1,000 angstroms.

The ozone flushing treatment performed before and/or after forming the upper hydrogen diffusion barrier layer 140 is more preferably performed at a relatively low temperature (i.e., about 200 to 450° C.) compared to the ozone flushing treatment performed before and/or after forming the lower hydrogen diffusion barrier layer 126. This is because the metal interconnections 136 and 130 are located under the upper hydrogen diffusion barrier layer 140. The ozone flushing treatment supplies a large amount of oxygen atoms to minimize oxygen vacancies in the ferroelectric layer, thereby preventing deterioration due to hydrogen atoms generated in a subsequent process.

Referring to FIG. 2G, a passivation layer 142 is formed on the upper hydrogen diffusion barrier layer 140. The passivation layer 142 may be made of silicon nitride, silicon oxide nitride, silicon oxide, or a combination thereof. Although hydrogen atoms are readily generated during the formation of the passivation layer 142, the ferroelectric capacitors 124 are not damaged because of the presence of the upper and lower hydrogen diffusion barrier layers 140, 126.

In summary, at least one hydrogen diffusion barrier layer is preferably formed over ferroelectric capacitors of a FRAM device. In addition, an ozone flushing treatment is preferably performed before and/or after the formation of the hydrogen diffusion barrier layer(s). It is therefore possible to minimize oxygen vacancies in the ferroelectric layer and prevent deterioration of the ferroelectric capacitors due to hydrogen atoms generated in a subsequent process.

What is claimed is:

1. A method of forming a semiconductor device, comprising;
applying an ozone flushing treatment to a surface of a semiconductor substrate; and
forming a hydrogen diffusion barrier layer on the surface of the semiconductor substrate.

2. The method according to claim 1, wherein the ozone flushing treatment is performed using an ozone concentration of about 100 to 300 g/m³ at a temperature of about 200 to 550° C. for approximately 1 to 10 minutes.

3. The method according to claim 1, wherein the hydrogen diffusion barrier layer is made of aluminum oxide.

4. The method according to claim 3, wherein trimethyl aluminum gas is used as an aluminum precursor and wherein ozone or H₂O is used as an oxygen precursor.

5. The method according to claim 1, wherein the hydrogen diffusion barrier layer is formed using an atomic layer deposition (ALD) technique.

6. The method according to claim 1, wherein the ozone flushing treatment is an ozone flushing pre-treatment.

7. The method according to claim 6, further comprising applying an ozone flushing post-treatment to the substrate having the hydrogen diffusion barrier layer.

8. The method according to claim 7, wherein the ozone flushing post-treatment is performed with an ozone concentration of about 100 to 300 g/m³ at a temperature of between about 200 to 550° C. for approximately 1 to 10 minutes.

9. A method of fabricating a semiconductor device comprising:
forming a lower interlayer dielectric layer on a semiconductor substrate;
forming a ferroelectric capacitor on the lower interlayer dielectric layer, the ferroelectric capacitor being electrically connected to the semiconductor substrate through a capacitor contact hole that penetrates the lower interlayer dielectric layer;
applying a first ozone flushing pre-treatment to the substrate having the ferroelectric capacitor;
forming a lower hydrogen diffusion barrier layer on the surface of the oxygen-flushed substrate;
forming an upper interlayer dielectric layer on the lower hydrogen diffusion barrier layer;
forming a metal interconnection on the upper interlayer dielectric layer, the metal interconnection being electrically connected the ferroelectric capacitor through a via hole that penetrates the upper interlayer dielectric layer and the lower hydrogen diffusion barrier layer;
applying a second ozone flushing pre-treatment to the substrate having the metal interconnection;
forming an upper hydrogen diffusion barrier layer on the entire surface of the resultant structure where the second ozone flushing pre-treatment is applied; and
forming a passivation layer on the upper hydrogen diffusion barrier layer.

10. The method according to claim 9, further comprises forming a buffer insulation layer on the entire surface of the substrate including the metal interconnection prior to application of the second ozone flushing pre-treatment.

11. The method according to claim 9, wherein the first ozone flushing pretreatment is performed with an ozone concentration of about 100 to 300 g/m³ at a temperature of about 200 to 550° C. for approximately 1 to 10 minutes, and wherein the second ozone flushing pre-treatment is performed with an ozone concentration of about 100 to 300 g/m³ at a temperature of about 200 to 450° C. for approximately 1 to 10 minutes.

12. The method according to claim 9, wherein the lower and upper hydrogen diffusion barrier layers are made of aluminum oxide or tantalum oxide (Ta₂O₅).

13. The method according to claim 12, wherein the aluminum oxide layer is formed by an atomic layer deposition (ALD) technique using a trimethyl aluminum gas as an aluminum precursor and ozone or H₂O as an oxygen precursor.

14. The method according to claim 9, further comprising applying a first ozone flushing post-treatment to the lower hydrogen diffusion barrier layer prior to formation of the upper interlayer dielectric layer.

15. The method according to claim 9, further comprising applying a second ozone flushing post-treatment to the upper hydrogen diffusion barrier layer prior to formation of the passivation layer.

16. A semiconductor device, comprising:
a lower interlayer dielectric layer formed on a semiconductor substrate;
a ferroelectric capacitor formed on the lower interlayer dielectric layer, the ferroelectric capacitor being electrically connected to the semiconductor substrate through a capacitor contact hole that penetrates the lower interlayer dielectric layer, wherein the substrate including the ferroelectric capacitor has an oxygen-flushed top surface;
a lower hydrogen diffusion barrier layer covering the ferroelectric capacitor;
an upper interlayer dielectric layer formed on the lower hydrogen diffusion barrier layer;
a metal interconnection formed on the upper interlayer dielectric layer, the metal interconnection being electrically connected to the ferroelectric capacitor through a via hole that penetrates a predetermined region of the upper interlayer dielectric layer and the lower hydrogen diffusion barrier layer;
an upper hydrogen diffusion barrier layer formed over the metal interconnection; and
a passivation layer formed on the upper hydrogen diffusion barrier layer.

17. The device according to claim 16, wherein the upper and lower hydrogen diffusion barrier layers are an aluminum trioxide layer or a Ta₂O₅ layer.

18. The device according to claim 16, further comprising a buffer insulation layer between the metal interconnection and the upper hydrogen diffusion barrier layer.

19. The device according to claim 18, wherein the buffer insulation layer is a PE-TEOS layer having a thickness of about 1,000 to 6,000 angstroms.

20. The device according to claim 16, further comprising:
a transistor formed at the semiconductor substrate and covered with the lower interlayer dielectric layer, the transistor having a gate electrode and source/drain regions; and
a bit line formed within the lower interlayer dielectric layer, the bit line being electrically connected to the drain region of the transistor.
